(19) United States
(12) Patent Application Publication
(10) Pub. No.: US 2019/0084428 A1
(43) Pub. Date: Mar. 21, 2019

(54) Photovoltaic Module and Container Equipped Therewith

(71) Applicant: Fraunhofer-Gesellschaft Zur Förderung Der Angewand Angewandten Forschung E.V., München (DE)

(72) Inventors: Matthieu Ebert, Freiburg (DE); Max Mittag, Freiburg (DE)

(21) Appl. No.: 16/083,307

(22) PCT Filed: Mar. 7, 2017
(86) PCT No.: PCT/EP2017/055260

§ 371 Date: Sep. 7, 2018

(30) Foreign Application Priority Data
Mar. 9, 2016 (DE) 10 2016 203 813.3

(51) Int. Cl. B60L 8/00; B60R 16/033; H01L 31/0392; H02S 20/20

(52) U.S. Cl. CPC B60L 8/003; H02S 20/20; H01L 31/0392; B60R 16/033

(57) ABSTRACT

The invention relates to a cooling container or swap body or box body or recreational vehicle, comprising at least one photovoltaic module (1) having at least one transparent cover layer, at least one photovoltaic cell, and at least one carrier layer, wherein at least one thermal insulation layer is present between the carrier layer and the photovoltaic cell, wherein at least the transparent cover layer, the photovoltaic cell, the thermal insulation layer, and the carrier layer are joined to each other over the entire area.

### BACKGROUND

The invention relates to a photovoltaic module with at least one transparent cover layer, at least one photovoltaic cell and at least one carrier layer. The invention also relates to a vehicle or a container equipped with a photovoltaic module.

Photovoltaic modules having a plurality of photovoltaic cells are known from practice. In order to protect the photovoltaic cells from weather influences, the photovoltaic module has at least one transparent cover layer through which sunlight can enter the photovoltaic module and can be absorbed in the photovoltaic cell. The rear side of the photovoltaic module is closed with at least one carrier layer, so that the penetration of moisture and subsequent damage to the module are avoided. The transparent cover layer, the carrier layer and embedding films possibly arranged therebetween can be closed with an edge seal, which contains an aluminum profile, for example.

Furthermore, it is known from practice to produce a panel material by gluing a polyurethane foam to one or two cover layers over the entire surface. The cover layers can here be made of aluminum sheet, steel sheet or a plastic material. Vehicle superstructures can then be produced from this panel material, for example box bodies of trucks, containers or camper shells for camper vehicles.

If such a vehicle is to be equipped with photovoltaic cells, for example to make a camper vehicle independent of the power supply from the public power grid, the photovoltaic modules known per se are usually mounted on the camper shell and/or the box body. This can be done either by gluing or by holding elements made of metal or a plastic material, which are connected to the vehicle and engage the frame of the photovoltaic module.

However, this approach has the disadvantage that the photovoltaic modules have a high weight, which adversely affects the payload of the vehicle and its center of gravity. Furthermore, the photovoltaic modules have a large overall height, so that the clearance height and the aerodynamics of the vehicle can be negatively affected.

There is therefore a need to reliably integrate photovoltaic cells into a vehicle roof to supply energy to vehicle systems.

### SUMMARY

According to invention, this object is achieved by a cooling container, a swap body, a box body or a camper vehicle according to claim 1. Advantageous developments of the invention are found in the subclaims.

The invention proposes to equip the photovoltaic module with at least one transparent cover layer. The transparent cover layer is transparent or translucent at least in part of the electromagnetic spectrum to thus allow light to enter the photovoltaic cells. In accordance with the invention, transparency or translucency is assumed if, at least in a segment of the electromagnetic spectrum which can be used to generate electricity, more than 50%, more than 60% or more than 80% of incident radiation is capable of penetrating the transparent cover layer. In some embodiments of the invention, the spectral range, within which the cover layer is transparent, can be adapted to the absorption behavior of the photovoltaic cells used. In some embodiments, the cover layer can be composed of a plurality of material layers and e.g. contain a laminated safety glass which combines at least one glass layer and at least one plastic film, which are joined together over their entire surface.

Furthermore, the photovoltaic module according to the invention contains at least one photovoltaic cell. The photovoltaic cell contains a semiconductor material which is provided with contact elements. On the absorption of incident electromagnetic radiation, electron-hole pairs are formed in the substrate of the photovoltaic cell and can be conducted via the contact elements as electrical voltage or electrical current. This electrical current can then be supplied to a consumer, e.g. a cooling unit or a lighting system.

Furthermore, the photovoltaic module according to the invention has at least one carrier layer, which can be made of steel sheet, aluminum or a plastic material, for example. The carrier layer provides the photovoltaic module with mechanical stability, prevents the penetration of moisture or other harmful compounds, such as oxygen or ammonia, into the photovoltaic modules and thus prevents them from being damaged.

According to the invention, it is proposed to insert at least one thermal insulation layer between the carrier layer and the photovoltaic cell. In this way, the photovoltaic module according to the invention can be used not only to generate electricity but also to thermally insulate an underlying room, which is at least partially limited by the photovoltaic module. Instead of first creating a container with a mechanical structure and thermal insulation and finally placing a photovoltaic module on top of it, the invention proposes to use a photovoltaic module that combines the functions of power generation and thermal insulation and, optionally, also mechanical stability in a single component. This makes it easier and quicker to produce such a container. In addition, in some embodiments of the invention, the photovoltaic modules according to the invention can weigh less than conventional known panel materials with additional photovoltaic modules arranged thereon. This creates a container with a favorable center of gravity position and increased payload, especially when installed in the roof area, since the dead weight of the container is reduced while the overall weight remains constant.

In some embodiments of the invention, the thermal insulation layer can have a thermal conductivity value of less than about 0.8 W·m·K⁻¹ or less than about 0.5 W·m·K⁻¹ or less than about 0.2 W·m·K⁻¹.

In some embodiments of the invention, the transparent cover layer can contain at least one layer of a glass and/or a silicone and/or an ethylene vinyl acetate and/or an ethylene tetrafluoroethylene and/or a polyvinyl butyral and/or a polyethylene and/or a polycarbonate and/or polymethyl methacrylate and/or ethylene tetrafluoroethylene. On the one hand, these materials have sufficient transparency to allow efficient power production through the photovoltaic cells. Furthermore, the transparent cover layer is provided to prevent weather influences from the photovoltaic cells and thus avoid premature aging and premature failure of the photovoltaic cells.

In some embodiments of the invention, the transparent cover layer can contain at least one layer of an elastic material or can consist of an elastic material to absorb mechanical stresses between the photovoltaic cells and the other material layers of the photovoltaic module and thus avoid breakage of the photovoltaic cells.

In some embodiments, the transparent cover layer can contain or consist of a plurality of individual layers of different materials. For example, an elastic material layer can be arranged directly on the photovoltaic cells, and a mechanically more stable material layer can be arranged thereabove and provides a mechanically stable and weatherproof isolation of the photovoltaic module from the environment.

In some embodiments of the invention, the thermal insulation layer can contain or consist of a polyurethane foam and/or a polystyrene foam and/or a foam glass. On the one hand, these materials have a light weight which is advantageous in particular in the case of mobile applications and only impairs the payload to be transported only to a minor extent. In addition, these materials can have closed pores, with the result that they are rot-proof and cannot be damaged by penetrating water. In the case of a polystyrene foam, an extruded polystyrene is particularly suitable for this purpose.

In some embodiments of the invention, the thermal insulation layer can have a thickness of about 30 mm to about 200 mm. In other embodiments of the invention, the thermal insulation layer can have a thickness of about 40 mm to about 150 mm. In yet other embodiments of the invention, the thermal insulation layer can have a thickness of about 50 mm to about 120 mm. On the one hand, thermal insulation layers of said thickness offer the advantage of sufficient thermal insulation and, on the other hand, these insulation layers have a small installation place, so that sufficient useful volume remains inside a container equipped with the photovoltaic module.

In some embodiments of the invention, the carrier layer can contain or consist of aluminum and/or steel and/or a plastic material. Depending on the planned application, the carrier layer can here be particularly lightweight or have high strength or impact resistance. As a result of the carrier layer, the photovoltaic module can, on the one hand, receive sufficient mechanical stability. Furthermore, the carrier layer can be designed to protect the underlying thermal insulation layer from damage or penetrating moisture.

In some embodiments of the invention, the carrier layer can have a thickness of about 0.2 mm to about 6 mm or of about 0.5 mm to about 5 mm or of about 1 mm to about 4 mm or of about 2 mm to about 3 mm. On the one hand, such carrier layers are sufficiently lightweight and require only little installation space and, on the other hand, can ensure sufficient mechanical stability of the photovoltaic module.

In some embodiments of the invention, at least one reinforcing element can be incorporated in the thermal insulation layer of the photovoltaic module. In some embodiments of the invention, the reinforcing element can contain or consist of aluminum or a plastic material. In some embodiments of the invention, the reinforcing element can have a fiber reinforcement, e.g. made of glass fiber or aramid fiber or carbon fiber. The reinforcing element can increase the mechanical stability of the photovoltaic module and thus the stability of a container manufactured or equipped with the photovoltaic module. For this purpose, the reinforcing element can have standard cross-sections, for example as U-beam or I-beam or box girder. A reinforcing element which contains or consists of aluminum, steel or another metal can provide the photovoltaic module according to the invention with high mechanical strength. In return, a reinforcing element made of a plastic material can improve the thermal insulation and avoid the occurrence of cold bridges.

### BRIEF DESCRIPTION OF THE DRAWINGS

The invention shall be described in more detail below by means of drawings without limiting the general inventive concept, wherein

FIG. 1 shows an embodiment of a vehicle equipped with the photovoltaic module according to the invention.

FIG. 2 shows a view of the photovoltaic module according to the invention.

FIG. 3 shows a cross-section through a first embodiment of the photovoltaic module according to the invention.

FIG. 4 shows a cross-section through a second embodiment of the photovoltaic module according to the invention.

FIG. 5 shows a cross section through a third embodiment of the photovoltaic module according to the invention.

### DETAILED DESCRIPTION

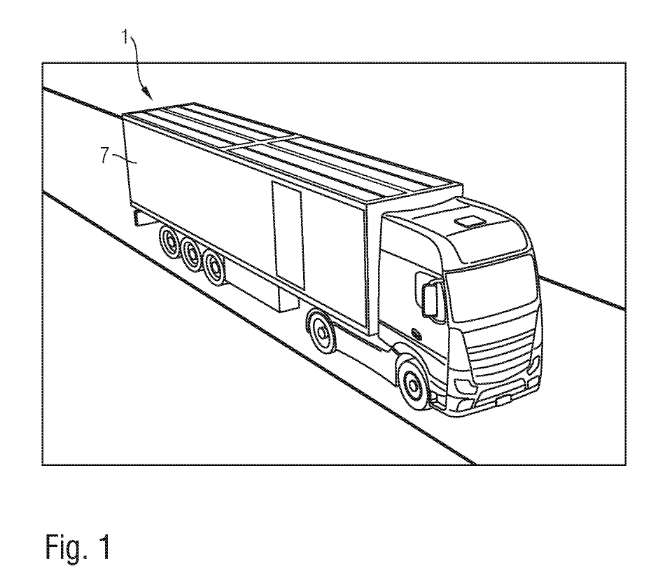

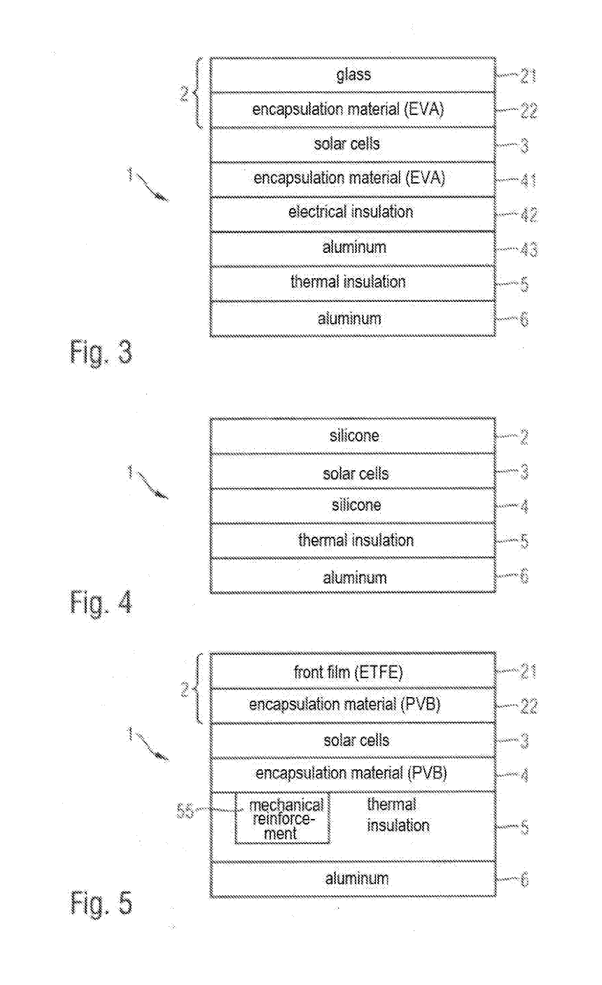

FIG. 1 shows a tractor unit with attached swap body 7. The swap body is designed as a cold store for transporting perishable goods. Here, the ceiling is formed from photovoltaic modules according to the invention, which, in addition to photovoltaic power generation, integrate thermal insulation, as explained in more detail below in FIGS. 3, 4 and 5.

In some embodiments, the side walls of the container can also be at least partially made of the photovoltaic modules according to the invention. However, since the power generation on the vertical surfaces is lower than that on the horizontal roof surface, it may make more economic sense to use generally known panel material with two cover layers and a rigid foam insulation arranged therebetween to produce the side walls. In this way, the container, which is shown in FIG. 1 and is mounted on a swap body, can be easily made without the additional assembly of photovoltaic modules on the roof increasing the weight, affecting the position of the center of gravity or requiring additional manufacturing effort. The photovoltaic module can here provide sufficient mechanical stability or form part of a flat structure without the need for additional support structures.

The electricity generated by the photovoltaic modules 1 can be used to operate a refrigerating machine both while stationary and while driving, so that the illustrated swap body is suitable for transporting perishable goods, with less fossil energy having to be used for cooling. As a result, the transport requires lower primary energy consumption.

In the same way as shown in FIG. 1 by means of a swap body 7, the photovoltaic module according to the invention can also be used in other embodiments of the invention to manufacture a refrigerated container, a box body or a camper shell of a camper vehicle or a caravan. Optionally, the container according to the invention can be additionally equipped with an inverter, a charge controller and/or a battery bank in order to thus provide sufficient energy reserves for cooling even during the low-sun night hours or in bad weather conditions without the refrigerating machine having to be operated by a diesel generator set.

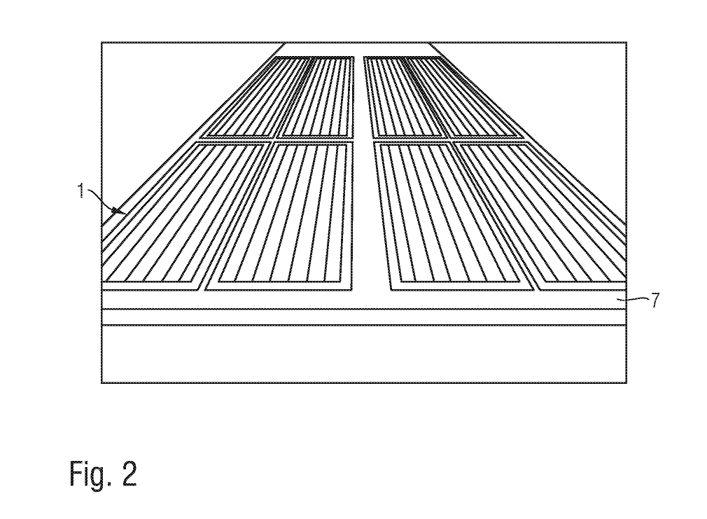

FIG. 2 shows once again a view of the photovoltaic module according to the invention. It is clear from FIG. 2 that the photovoltaic cells with their cover layer are an integral part of the ceiling of the cooling container 7. In contrast to previously known solutions, the photovoltaic modules are not screwed or glued to the container with a frame, but the container ceiling consists directly of photovoltaic modules which additionally provide a thermal insulation.

FIGS. 3, 4 and 5 explain in more detail different embodiments of the photovoltaic module according to the invention in cross-section. Here, FIG. 3 shows a first embodiment, FIG. 4 shows a second embodiment and FIG. 5 shows a third embodiment. Identical components of the invention are provided with the same reference signs, and therefore the description of the second and third embodiments is limited to the essential differences.

FIG. 3 shows a photovoltaic module 1, which has a transparent cover layer 2. The transparent cover layer 2 has an outside facing the environment and an inside facing the photovoltaic cells 3. In the illustrated embodiment, the cover layer 2 contains two material layers 21 and 22 made of different materials. The outer material layer 21 is here made of glass, for example a pre-stressed single-pane safety glass or a laminated safety glass. In the case of laminated glass, the glass layer 21 contains additional intermediate layers of a plastic film which are not shown in the drawing. The glass 21 has a high resistance to environmental influences and an extremely low diffusion constant for penetrating moisture, so that the subsequent components of the photovoltaic module, in particular the photovoltaic cells 3, cannot be damaged by penetrating moisture.

A layer of ethylene vinyl acetate 22 is arranged below the glass 21. This layer is used to avoid mechanical stresses between the glass 21 and the photovoltaic cells 3 as this elastic layer 22 absorbs different thermal expansions or stress peaks by vibrations during transport and introduces them over a large area into the respective layers above and below.

The photovoltaic cells 3 can be cells which are known per se and are made of amorphous or crystalline silicon, or can also be solar cells which are based on the material copper-indium-gallium-diselenide (CIGS). Due to the higher efficiency and the limited surface area of the vehicle roof, crystalline solar cells can be preferred in some embodiments of the invention. The photovoltaic cells have, in a manner known per se, two contacts which are connected to corresponding p- and n-doped areas. On the arrival of electromagnetic radiation above the band gap energy, electron-hole pairs are thus formed, which can be dissipated as electrical current via the two connection contacts. For this purpose, the photovoltaic module 1 may have wiring or busbars, which are, however, not shown in the drawings. In some embodiments of the invention, these can also be guided in the thermal insulation 5, which offers sufficient installation space due to its thickness.

FIG. 3 also shows a thermal insulation layer 5, which contains a rigid foam, for example. In some embodiments, the rigid foam can be selected from a polyurethane foam or from extruded polystyrene. This ensures that the thermal insulation not only reduces the heat entry into the container equipped with the photovoltaic module, but also contributes to the mechanical stability of the photovoltaic module.

Finally, there is a carrier layer 6 on the side of the photovoltaic module that faces the inside of the container. In the illustrated embodiment, the carrier layer 6 is made of an aluminum sheet having a thickness of 1.5 mm. In other embodiments of the invention, the carrier layer can be thicker or thinner. In some embodiments, the carrier layer can also be made of steel sheet or a plastic material. The carrier layer can be used to avoid mechanical damage to the thermal insulation. Furthermore, the carrier layer 6 can reduce or prevent the penetration of moisture into the thermal insulation, so that the carrier layer 6 also acts as a vapor barrier. Finally, the carrier layer 6 can make a significant contribution to the mechanical stability of the photovoltaic module, so that the photovoltaic cells 3 are not damaged during the handling of the photovoltaic module and the container equipped with photovoltaic module 1 has sufficient inherent stability, even without a supplementary frame structure in some cases.

FIG. 3 also shows optional intermediate layers 41, 42 and 43, which do not have to be present in every embodiment of the photovoltaic module according to the invention. Thus, the first intermediate layer 41 is also made of ethylene vinyl acetate, as is the second layer 22 of the cover layer 2. In this case, too, the elastic first intermediate layer 41 serves to remove mechanical stress between the solar cells and the adjacent components of the photovoltaic module and to prevent moisture from penetrating. The second layer 22 of the cover layer 2 and the elastic first intermediate layer 41 can be welded together in partial areas to achieve a tight seal.

In some embodiments of the invention, a second intermediate layer 42 can still be present which serves for electrical insulation. For example, the second intermediate layer 42 can be or contain a polymer film. In some embodiments of the invention, the film can have a thickness between about 0.1 mm and about 0.5 mm.

Finally, the illustrated embodiment has a third intermediate layer 43, which contains an aluminum sheet. The third intermediate layer 43 serves to mechanically reinforce the photovoltaic module, so that even large containers, such as swap bodies having a width of 2.4 m, can easily be produced with the photovoltaic module without the ceiling area becoming unstable. In other embodiments of the invention, the third intermediate layer 43 can also consist of another material, for example steel or a plastic material. A plastic material can contain a fiber reinforcement and a binder, e.g. glass fibers, carbon fibers or aramid fibers in a thermoset or thermoplastic matrix.

The individual components of the photovoltaic module according to the invention can be connected to each other over their entire surface, for example by full-surface bonding or by welding, with the result that a frame or other edge seal can be dispensed with. This allows photovoltaic modules to be connected according to the invention by gluing, welding or by frame elements to one another to thus compose containers of any form and size.

A second embodiment of the invention is illustrated in FIG. 4. In this case, the transparent cover layer 2 is made of a silicone which is break-proof and lightweight, making the photovoltaic module according to the second embodiment particularly suitable for smaller vehicles or for containers with a large payload.

The photovoltaic cells 3 are disposed below the transparent cover layer 2, as explained above. The thermal insulation layer 5 and the carrier layer 6 are in turn arranged below the photovoltaic cells. These layers can also be applied, as already explained in FIG. 3.

The second embodiment also contains an optional intermediate layer 4, which in this case is also made of silicone between the photovoltaic cell 3 and the thermal insulation layer 5. It is thus possible to interconnect the transparent cover layer 2 and the intermediate layer 4, at least in their edge area, by means of welding, so that the photovoltaic cells 3 are completely embedded in the silicone and are thus reliably protected from weather influences. Due to the thermal insulation layer 5 and the carrier layer 6, the photovoltaic cells 3 are also protected from their underside against mechanical damage and moisture.

A third embodiment of the present invention is explained in FIG. 5. In this case, too, the transparent cover layer 2 is composed of a first material layer 21 and a second material layer 22. The first material layer 22 here contains ethylene tetrafluoroethylene, which is lighter and has a higher impact resistance compared to glass, so that the weight of a container made with the photovoltaic module 1 in accordance with the third embodiment can be reduced and the resistance to punctiform loads, for example rockfall, can be increased.

The first material layer 21 is bonded over the entire area to a second material layer 22 made of polyvinyl butyral. It is used to prevent moisture ingress and thus to avoid premature aging of the photovoltaic cells 3. For this purpose, the photovoltaic cells 3 can be embedded on an optional intermediate layer 4, which can also consist of polyvinyl butyral or contains this material. In this case, too, the intermediate layer 4 can be welded to the transparent cover layer 2 in the edge area of the photovoltaic cells 3 to achieve a particularly tight seal. The intermediate layer 4 can also be used in this case to absorb mechanical stresses at different thermal expansion.

FIG. 5 shows a thermal insulation layer 5, which can consist of a hard foam as described above. A mechanical reinforcement 55 can be embedded in this thermal insulation layer 5, e.g. in the form of a box girder, an I-beam or a U-beam. This allows an improved strength of the container equipped with the photovoltaic module to be achieved. To avoid cold bridges, the reinforcing element 55 can have a smaller cross-section than the thermal insulation layer 5, so that the carrier layer 6 is not in contact with the mechanical reinforcing element.

A carrier layer 6 of aluminum, steel or a plastic material is again the sealing on the inside of the photovoltaic module as described above.

It goes without saying that the invention is not limited to the illustrated embodiments. Therefore, the above description should not be considered limiting but explanatory. The following claims should be understood in such a way that a stated feature is present in at least one embodiment of the invention. This does not exclude the presence of further features. If the claims and the above description define “first” and “second” embodiments, this designation serves to distinguish between two similar embodiments without determining a ranking order.

1-12. (canceled)

13. A cooling container, swap body (7), box body, or camper vehicle comprising:
at least one photovoltaic module (1), said photovoltaic module comprising:
a transparent cover layer (2);
a photovoltaic cell (3);
a carrier layer (6); and
a thermal insulation layer (5) between the carrier layer (6) and the photovoltaic cell (3),
wherein at least two of the transparent cover layer (2), the photovoltaic cell (3), the thermal insulation layer (5) and the carrier layer (6) are joined to one another over an entire area of said at least two of the transparent cover layer (2), the photovoltaic cell (3), the thermal insulation layer (5) and the carrier layer (6).

14. The cooling container, swap body (7), box body, or camper vehicle of claim 1, wherein the transparent cover layer (2) contains at least one layer (21, 22) selected from the group consisting of: glass, silicone, ethylene vinyl acetate, ethylene tetrafluoroethylene, polyvinyl butyral, polymethyl methacrylate, and ethylene tetrafluoroethylene.

15. The cooling container, swap body (7), box body, or camper vehicle of claim 1, wherein the transparent cover layer (2) comprises a plurality of individual layers (21, 22) of different materials.

16. The cooling container, swap body (7), box body, or camper vehicle of claim 1, wherein the thermal insulation layer (5) comprises material selected from the group consisting of: polyurethane foam, polystyrene foam, and foam glass.

17. The cooling container, swap body (7), box body, or camper vehicle of claim 1, wherein the thermal insulation layer (5) has a thickness of about 30 mm to about 200 mm.

18. The cooling container, swap body (7), box body, or camper vehicle of claim 1, wherein the carrier layer (6) comprises material selected from the group consisting of aluminum, steel, and plastic and the carrier layer (6) has a thickness of about 0.2 mm to about 6 mm.

19. The cooling container, swap body (7), box body, or camper vehicle of claim 1, wherein at least one reinforcing element (55) is incorporated in the thermal insulation layer (5).

20. The cooling container, swap body (7), box body, or camper vehicle of claim 1, wherein at least one intermediate layer (41, 42, 43) is arranged between the thermal insulation layer (5) and the photovoltaic cell (3).

21. The cooling container, swap body (7), box body, or camper vehicle of claim 20, wherein the intermediate layer (41, 42) comprises material selected from the group consisting of: silicone, polyvinyl butyral, and ethylene tetrafluoroethylene.

22. The cooling container, swap body (7), box body, or camper vehicle of claim 20, wherein at least the cover layer (2), or the intermediate layer (41, 42, 43), or the thermal insulation layer (5), or the carrier layer (6) are glued or welded to an adjacent layer over an entire area of the glued or welded layers.

23. The cooling container, swap body (7), box body, or camper vehicle of claim 19, wherein the reinforcing element (55) comprises aluminum, or plastic material.

24. The cooling container, swap body (7), box body, or camper vehicle of claim 1, wherein the at least two of the transparent cover layer (2), the photovoltaic cell (3), the thermal insulation layer (5) and the carrier layer (6) are joined by gluing or by welding.

25. The cooling container, swap body (7), box body, or camper vehicle of claim 20, wherein said transparent cover layer (2) and said intermediate layer (41, 42, 43) have edge areas surrounding said photovoltaic cell (3), and the edge area of said transparent cover layer (2) is joined to the edge area of said intermediate layer (41, 42, 43) to achieve a seal surrounding said photovoltaic cell (3).

26. The cooling container, swap body (7), box body, or camper vehicle of claim 25, wherein said transparent cover layer (2) and said intermediate layer (41, 42, 4) are silicone, and the joining of said transparent cover layer (2) and said intermediate layer (41, 42, 4) embeds the photovoltaic cell (3) in silicone.

27. The cooling container, swap body (7), box body, or camper vehicle of claim 1, wherein said transparent cover layer (2) comprises a first material layer (21) and a second material layer (22) bonded to each other, said first material layer (21) is impact and puncture resistant and said second layer (22) is elastic.

28. The cooling container, swap body (7), box body, or camper vehicle of claim 27, comprising an intermediate layer (41, 4) of the same elastic material as said second material layer (22) and said intermediate layer (41, 4) is joined to said second material layer (22) so that the photovoltaic cell (3) is embedded in said elastic material.

29. The cooling container, swap body (7), box body, or camper vehicle of claim 28, wherein said elastic layer is selected from the group consisting of: silicone, polyvinyl butyral, and ethylene vinyl acetate.
